(19) United States
(12) Patent Application Publication
(10) Pub. No.: US 2026/0164622 A1
(43) Pub. Date: Jun. 11, 2026

(54) AUTOMOBILE HEAT DISSIPATION DEVICE HAVING MODIFIED SURFACE

(71) Applicant: AMULAIRE THERMAL TECHNOLOGY, INC., New Taipei City (TW)

(72) Inventors: YI-HSIN HUANG, New Taipei City (TW); KUO-WEI LEE, New Taipei City (TW); TZE-YANG YEH, New Taipei City (TW); CHING-MING YANG, New Taipei City (TW)

(21) Appl. No.: 18/976,575

(22) Filed: Dec. 11, 2024

(51) Int. Cl. H05K 7/20

(52) U.S. Cl. CPC H05K 7/20854; H05K 7/20154

(57) ABSTRACT

An automobile heat dissipation device having a modified surface includes a metal heat dissipation device and a silver metal layer. The metal heat dissipation device has a first and a second heat dissipation surface. The silver metal layer is formed on the first heat dissipation surface of the metal heat dissipation device by arc ion plating (AIP), so as to form a surface modification layer on the metal heat dissipation device. A surface of the surface modification layer is distributed with a plurality of holes that each have a diameter of from 0.1 μm to 30 μm and a plurality of metal particles that each have a size of less than 30 μm, and the surface of the surface modification layer acts as a subsequent silver sintered interface, so that the silver sintered interface is joined to at least one automobile electronic module by silver sintering.

### FIELD OF THE DISCLOSURE

The present disclosure relates to an automobile heat dissipation device, and more particularly to an automobile heat dissipation device having a modified surface.

### BACKGROUND OF THE DISCLOSURE

High heat is often generated during operation of conventional automobile electronic modules, such as insulated gate bipolar transistor (IGBT) modules and advanced driver-assistance system (ADAS) modules. If proper heat dissipation measures are not adopted, the temperature of the automobile electronic modules may exceed an allowable temperature, thereby resulting in deterioration of performance and damage.

### SUMMARY OF THE DISCLOSURE

In response to the above-referenced technical inadequacies, the present disclosure provides an automobile heat dissipation device having a modified surface.

In order to solve the above-mentioned problems, one of the technical aspects adopted by the present disclosure is to provide an automobile heat dissipation device having a modified surface, and the automobile heat dissipation device includes a metal heat dissipation device and a silver metal layer. The metal heat dissipation device has a first heat dissipation surface and a second heat dissipation surface that is configured to contact a coolant or air. The silver metal layer is formed on the first heat dissipation surface of the metal heat dissipation device by arc ion plating (AIP), so as to form a surface modification layer on the metal heat dissipation device. A surface of the surface modification layer is distributed with a plurality of holes that each have a diameter of from 0.1 μm to 30 μm and a plurality of metal particles that each have a size of less than 30 μm, and the surface of the surface modification layer acts as a subsequent silver sintered interface, so that the silver sintered interface is joined to at least one automobile electronic module by silver sintering.

In one of the possible or preferred embodiments, the surface modification layer is a film layer having a thickness of from 0.5 μm to 10 μm.

In one of the possible or preferred embodiments, the metal heat dissipation device is a water-cooled metal heat dissipation device or an air-cooled metal heat dissipation device.

In one of the possible or preferred embodiments, the metal heat dissipation device is a closed metal heat dissipation device or a semi-open metal heat dissipation device.

In one of the possible or preferred embodiments, an outer portion of the metal heat dissipation device is formed to have a fin structure, and the second heat dissipation surface of the metal heat dissipation device is a surface of the fin structure.

In one of the possible or preferred embodiments, an inner portion of the metal heat dissipation device is formed to have a fin structure, and the second heat dissipation surface of the metal heat dissipation device is a surface of the fin structure.

In one of the possible or preferred embodiments, the metal heat dissipation device is made of at least one of copper, aluminum, a copper alloy, or an aluminum alloy.

In one of the possible or preferred embodiments, the metal heat dissipation device has an initial surface modification layer, and a surface of the initial surface modification layer acts as the first heat dissipation surface of the metal heat dissipation device.

In one of the possible or preferred embodiments, the metal heat dissipation device has an initial surface modification layer, a surface of the initial surface modification layer acts as the first heat dissipation surface of the metal heat dissipation device, and one or more metal layers are formed between the silver metal layer and the first heat dissipation surface of the metal heat dissipation device.

In one of the possible or preferred embodiments, the silver metal layer is a patterned silver metal layer that is partially formed on the first heat dissipation surface of the metal heat dissipation device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a partial schematic side view of an automobile heat dissipation device according to a first embodiment of the present disclosure;

FIG. 2 is a partial schematic side view of the automobile heat dissipation device and an automobile electronic module according to the first embodiment of the present disclosure;

FIG. 3 is a partial schematic side view of an automobile heat dissipation device according to a second embodiment of the present disclosure;

FIG. 4 is a partial schematic side view of an automobile heat dissipation device according to a third embodiment of the present disclosure;

FIG. 5 is a partial schematic side view of an automobile heat dissipation device according to a fourth embodiment of the present disclosure;

FIG. 6 is a partial schematic side view of an automobile heat dissipation device according to a fifth embodiment of the present disclosure; and

FIG. 7 is a partial schematic side view of an automobile heat dissipation device according to a sixth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### FIRST EMBODIMENT

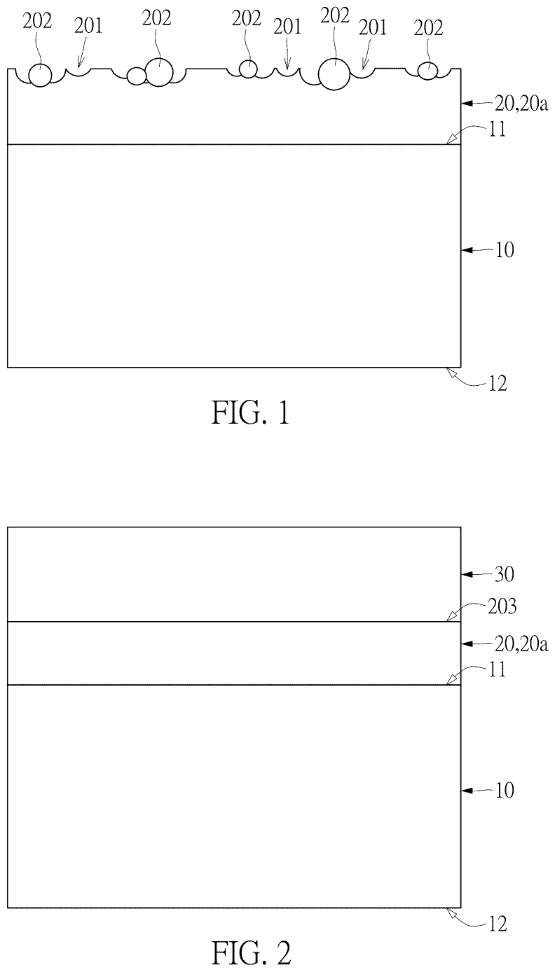

Referring to FIG. 1 to FIG. 2, a first embodiment of the present disclosure provides an automobile heat dissipation device having a modified surface. The automobile heat dissipation device mainly includes a metal heat dissipation device 10 and a silver metal layer 20.

In this embodiment, the metal heat dissipation device 10 can be made of copper, aluminum, a copper alloy, or an aluminum alloy. Furthermore, the metal heat dissipation device 10 can be a water-cooled metal heat dissipation device or an air-cooled metal heat dissipation device, or can be a closed metal heat dissipation device or a semi-open metal heat dissipation device. The metal heat dissipation device 10 has a first heat dissipation surface 11 and a second heat dissipation surface 12 that is configured to contact a coolant (e.g., water or ethylene glycol) or air. The first heat dissipation surface 11 and the second heat dissipation surface 12 are located at different positions of the metal heat dissipation device 10.

The silver metal layer 20 in this embodiment is formed on the first heat dissipation surface 11 of the metal heat dissipation device 10 by arc ion plating (AIP), thereby forming a surface modification layer 20a on the metal heat dissipation device 10. In this way, the metal heat dissipation device 10 has a modified surface. Moreover, a surface of the surface modification layer 20a that is formed by arc ion plating (AIP) is distributed with a plurality of holes 201 that each have a diameter of from 0.1 μm to 30 μm, and a plurality of metal particles 202 that each have a size of less than 30 μm. In addition, the surface modification layer 20 a that is formed by arc ion plating (AIP) is a film layer having a thickness of from 0.5 μm to 10 μm, so that the film layer is dense and has strong adhesion.

In this embodiment, the surface of the surface modification layer 20a can act as a subsequent silver sintered interface 203, so that the silver sintered interface 203 is joined to at least one automobile electronic module 30 by silver sintering (as shown in FIG. 2). The automobile electronic module 30 in this embodiment can be an insulated gate bipolar transistor (IGBT) module or an automotive advanced driver assistance system (ADAS) module. Through formation of the surface modification layer 20a on the first heat dissipation surface 11 of the metal heat dissipation device 10 by arc ion plating (AIP), and through use of the surface of the surface modification layer 20a as the subsequent silver sintered interface 203, strengthened connection between the metal heat dissipation device 10 and the automobile electronic module 30 can be achieved. This enables high heat generated during operation of the automobile electronic module 30 to be efficiently conducted to the first heat dissipation surface 11 of the metal heat dissipation device 10, and then to be dissipated through the second heat dissipation surface 12 of the metal heat dissipation device 10 via contact with water or air.

### SECOND EMBODIMENT

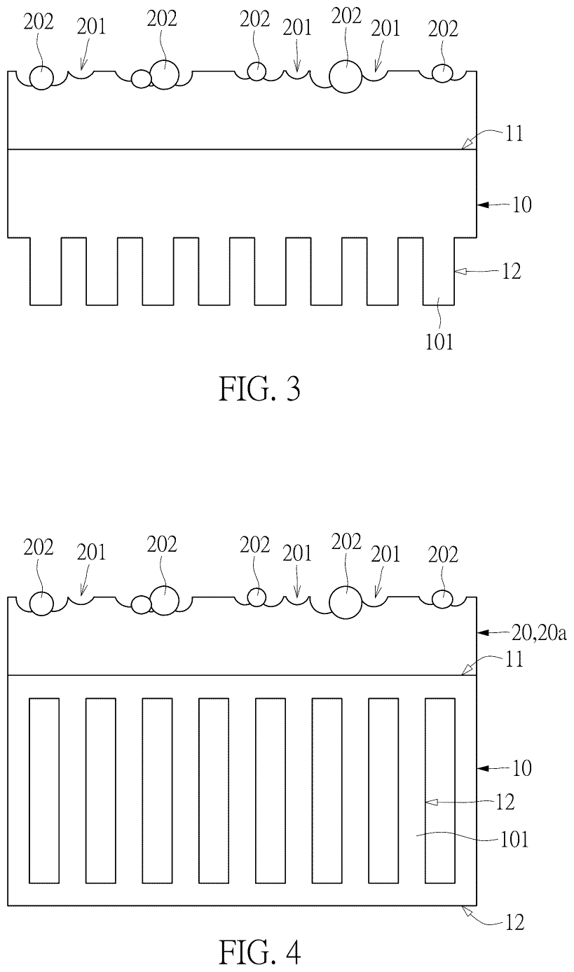

Reference is made to FIG. 3, which shows a second embodiment of the present disclosure. This embodiment is substantially the same as the first embodiment, and differences therebetween are described below.

In this embodiment, the metal heat dissipation device 10 can be the water-cooled metal heat dissipation device or the air-cooled metal heat dissipation device. Furthermore, an outer portion of the metal heat dissipation device 10 is formed to have a fin structure 101, and the second heat dissipation surface 12 of the metal heat dissipation device 10 is a surface of the fin structure 101.

### THIRD EMBODIMENT

Reference is made to FIG. 4, which shows a third embodiment of the present disclosure. This embodiment is substantially the same as the first embodiment, and differences therebetween are described below.

In this embodiment, in addition to being the water-cooled or air-cooled metal heat dissipation device, the metal heat dissipation device 10 can also be the closed or semi-open metal heat dissipation device. Furthermore, an inner portion of the metal heat dissipation device 10 is formed to have the fin structure 101, and the second heat dissipation surface 12 of the metal heat dissipation device is the surface of the fin structure 101.

### FOURTH EMBODIMENT

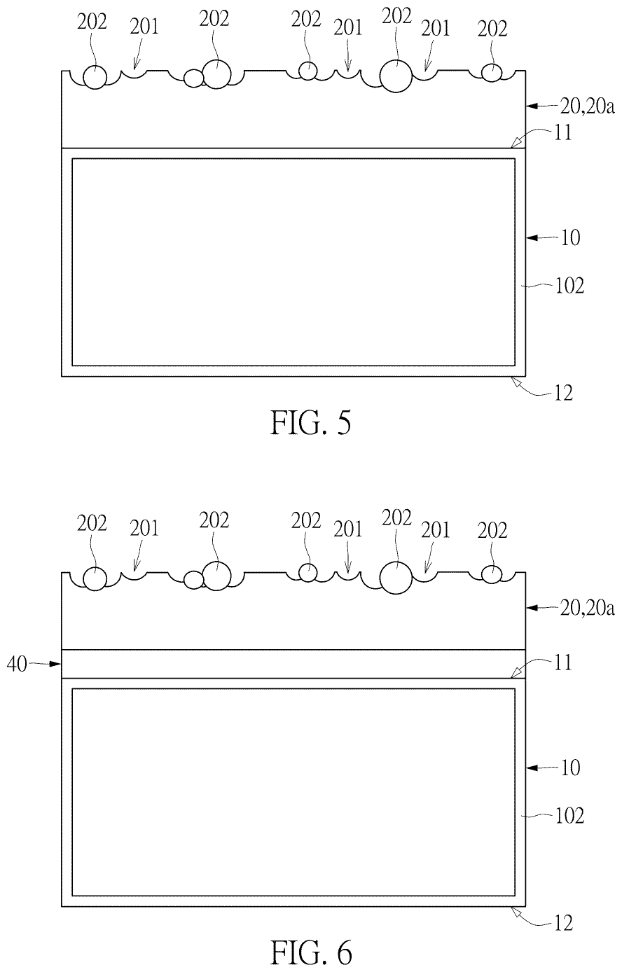

Reference is made to FIG. 5, which shows a fourth embodiment of the present disclosure. This embodiment is substantially the same as the first embodiment, and differences therebetween are described below.

In this embodiment, the metal heat dissipation device 10 has an initial surface modification layer 102 disposed on an initial surface thereof, and a surface of the initial surface modification layer 102 acts as the first heat dissipation surface 11 of the metal heat dissipation device 10. Preferably, the initial surface modification layer 102 of the metal heat dissipation device 10 is a nickel-plated layer. That is, the metal heat dissipation device 10 has undergone pretreatment, and is a nickel-plated metal heat dissipation device, thereby enhancing surface wear and corrosion resistance. In this way, the service life of the metal heat dissipation device 10 can be increased.

### FIFTH EMBODIMENT

Reference is made to FIG. 6, which shows a fifth embodiment of the present disclosure. This embodiment is substantially the same as the first embodiment, and differences therebetween are described below.

In this embodiment, the metal heat dissipation device 10 has the initial surface modification layer 102 disposed on the initial surface thereof, and the surface of the initial surface modification layer 102 acts as the first heat dissipation surface 11 of the metal heat dissipation device 10. Furthermore, one or more metal layers 40 are formed between the silver metal layer 20 and the first heat dissipation surface 11 of the metal heat dissipation device 10. Specifically, the one or more metal layers 40 can be a copper-plated layer, a silver-plated layer, or a combination of both, so as to enhance corrosion resistance or bonding properties.

### SIXTH EMBODIMENT

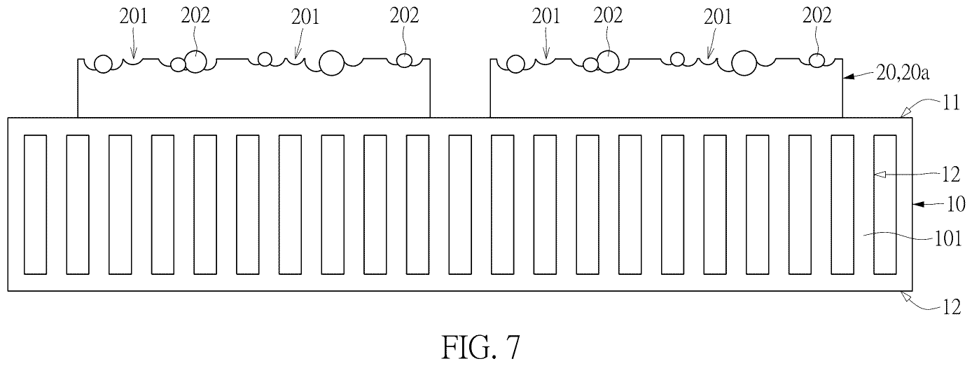

Reference is made to FIG. 7, which shows a sixth embodiment of the present disclosure. This embodiment is substantially the same as the first embodiment, and differences therebetween are described below.

In this embodiment, the silver metal layer 20 is a patterned silver metal layer that is partially formed on the first heat dissipation surface 11 of the metal heat dissipation device 10. Furthermore, the silver metal layer 20 covers an area that is less than 90% of an area of the first heat dissipation surface 11 of the metal heat dissipation device 10.

### Beneficial Effects of the Embodiments

In summary, the automobile heat dissipation device having the modified surface provided by the present disclosure includes a metal heat dissipation device and a silver metal layer. The metal heat dissipation device has a first heat dissipation surface and a second heat dissipation surface that is configured to contact a coolant or air. The silver metal layer is formed on the first heat dissipation surface of the metal heat dissipation device by arc ion plating (AIP), so as to form a surface modification layer on the metal heat dissipation device. A surface of the surface modification layer is distributed with a plurality of holes that each have a diameter of from 0.1 μm to 30 μm and a plurality of metal particles that each have a size of less than 30 μm, and the surface of the surface modification layer acts as a subsequent silver sintered interface, so that the silver sintered interface is joined to at least one automobile electronic module by silver sintering. Accordingly, through formation of the surface modification layer on the first heat dissipation surface of the metal heat dissipation device by arc ion plating (AIP), and through use of the surface of the surface modification layer as the subsequent silver sintered interface, strengthened connection between the metal heat dissipation device and the automobile electronic module can be achieved. This enables high heat generated during operation of the automobile electronic module to be efficiently conducted to the first heat dissipation surface of the metal heat dissipation device, and then to be dissipated through the second heat dissipation surface of the metal heat dissipation device via contact with water or air.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An automobile heat dissipation device having a modified surface, comprising:
a metal heat dissipation device having a first heat dissipation surface and a second heat dissipation surface that is configured to contact a coolant or air; and
a silver metal layer, wherein the silver metal layer is formed on the first heat dissipation surface of the metal heat dissipation device by arc ion plating (AIP), so as to form a surface modification layer on the metal heat dissipation device;
wherein a surface of the surface modification layer is distributed with a plurality of holes that each have a diameter of from 0.1 μm to 30 μm and a plurality of metal particles that each have a size of less than 30 μm, and the surface of the surface modification layer acts as a subsequent silver sintered interface, so that the silver sintered interface is joined to at least one automobile electronic module by silver sintering.

2. The automobile heat dissipation device according to claim 1, wherein the surface modification layer is a film layer having a thickness of from 0.5 μm to 10 μm.

3. The automobile heat dissipation device according to claim 1, wherein the metal heat dissipation device is a water-cooled metal heat dissipation device or an air-cooled metal heat dissipation device.

4. The automobile heat dissipation device according to claim 1, wherein the metal heat dissipation device is a closed metal heat dissipation device or a semi-open metal heat dissipation device.

5. The automobile heat dissipation device according to claim 1, wherein an outer portion of the metal heat dissipation device is formed to have a fin structure, and the second heat dissipation surface of the metal heat dissipation device is a surface of the fin structure.

6. The automobile heat dissipation device according to claim 1, wherein an inner portion of the metal heat dissipation device is formed to have a fin structure, and the second heat dissipation surface of the metal heat dissipation device is a surface of the fin structure.

7. The automobile heat dissipation device according to claim 1, wherein the metal heat dissipation device is made of at least one of copper, aluminum, a copper alloy, or an aluminum alloy.

8. The automobile heat dissipation device according to claim 1, wherein the metal heat dissipation device has an initial surface modification layer, and a surface of the initial surface modification layer acts as the first heat dissipation surface of the metal heat dissipation device.

9. The automobile heat dissipation device according to claim 1, wherein the metal heat dissipation device has an initial surface modification layer, a surface of the initial surface modification layer acts as the first heat dissipation surface of the metal heat dissipation device, and one or more metal layers are formed between the silver metal layer and the first heat dissipation surface of the metal heat dissipation device.

10. The automobile heat dissipation device according to claim 1, wherein the silver metal layer is a patterned silver metal layer that is partially formed on the first heat dissipation surface of the metal heat dissipation device.
